(19) United States
(12) Patent Application Publication
(10) Pub. No.: US 2024/0201262 A1
(43) Pub. Date: Jun. 20, 2024

(54) SYSTEM AND METHOD FOR INDUCTION MOTOR INTRA-CORE ROTOR BAR SURFACE MAGNETIC FIELD ANALYSIS

(71) Applicant: Brandon & Clark, Inc., Lubbock, TX (US)

(72) Inventor: Scott W. Clark, Lubbock, TX (US)

(73) Assignee: Brandon & Clark, Inc., Lubbock, TX (US)

(21) Appl. No.: 18/542,710

(22) Filed: Dec. 17, 2023

Related U.S. Application Data
(60) Provisional application No. 63/387,916, filed on Dec. 16, 2022.

(51) Int. Cl. G01R 31/34

(52) U.S. Cl. CPC G01R 31/34

(57) ABSTRACT

Disclosed herein is a system and method for induction motor intra-core rotor bar surface magnetic field analysis comprising a system and method of excitation and detection by placing a flux sensor array directly between core limbs of a non-contact exciter for observation of the rotor bar current flux pattern.

### BACKGROUND

In an effort to improve on intrinsic disadvantages in prior systems and methods for induction motor rotor magnetic field analysis testing associated with closed slot rotor designs, modifications to flux sensor and exciter placement, and to flux sensor signal processing, have been developed.

Prior rotor magnetic field analysis (“RMFA”) technology was developed with the primary method of current formation within the rotor cage of a test specimen via non-contact excitation (or exciter) sources. This excitation method precipitated a need to place flux sensors used to detect the resultant current flow in rotor cage bars at an axial distance from the excitation source to avoid flux sensor saturation from stray flux created by the non-contact exciter. This method works well in terms of excitation source efficiency. As the exciter and sensor are located at the same angular position relative to a rotor bar cage element under test, the excitation scheme needs only couple with several rotor bars in the angular area of testing. RMFA has proven to be effective at identifying minor and major defects in open slot rotor designs while only measuring rotor flux at a discrete axial position.

While RMFA was effective at improving on existing rotor testing techniques, however, there was a class of defect that could go undetected with the RMFA single axial position flux measurement technique. For example, a defect that does not disturb current flow along the entire length of a rotor bar may go undetected with RMFA technology. Therefore, it is necessary to perform the equivalent of an RMFA test at many axially locations to create a map of rotor flux over its entire surface through 360 degrees full rotation of the rotor, including the rotor end rings, to identify an axially isolated or spatially isolated rotor current flow variation resulting in an alteration to rotor flux from the design norm. This technique, however, creates a sensor-to-exciter interference condition in which the sensor can no longer be placed at the desired axial distance described in RMFA testing if the desire is to test many axial locations simultaneously via a flux sensor array. To resolve this exciter-to-sensor placement challenge, an alternative rotor excitation method was adopted in which current was indirectly injected into the rotor cage by a variable voltage source with a conductive connection made to each rotor end ring. This direct current injection method has the advantage of removing the non-contact exciter and its associated stray flux from sensor interference; however, its use comes with an efficiency penalty in that the current applied to the rotor divides across all rotor cage bar paths simultaneously rather than being concentrated along the bars of interest where the sensor array is located.

Further, both RMFA and prior surface rotor magnetic field analysis (“sRMFA”) testing applications on closed slot rotor designs can present challenges. One challenge associated with closed slot designs comes from machines that have been previously assembled and operated. After a closed slot machine has been operated, the slot closure area comprised of electrical steel is subject to field levels sufficient to permanently magnetize the surface of the rotor along its slot closure regions. This residual flux condition is detectable by the flux sensor technology used in RMFA and sRMFA and can create a bias pattern that complicates the statistical bar defect detection process. This residual flux challenge is not an issue at the rotor core manufacturing stage in that the machine has not yet been assembled, and no initial residual flux pattern has been formed.

Another challenge associated with closed slot designs is associated with the excitation method used; while direct injection will work fine with a closed slot unit, the efficiency losses may make it difficult to increase rotor cage current levels to overcome residual flux biasing. The more efficient non-contact excitation scheme suffers from a condition in which the majority of the exciter field travels within the rotor core surface above the rotor cage bar in a band and fails to couple the bars well. Further, this closed slot rotor exciter flux band creates an area where the rotor bar current derived field is not detectable.

### DESCRIPTION

To address the disadvantages and challenges discussed above, a new system and method of excitation and detection has been developed, which we call Intra-core sRMFA (“IcsRMFA”). This system and method may help eliminate or reduce the challenges and disadvantages found in RMFA testing. Specifically, we found that if a flux sensor array was placed directly between the core limbs (or core “jaw”) of a non-contact exciter (the limbs being the parallel arms of the exciter located outside the windings of the exciter, the core typically being constructed of electrical steel), the rotor bar current flux pattern was observable. Similar techniques we tried, however, previously came with challenges associated with signal magnitude.

To overcome these challenges, we found that unique data processing may be used with the IcsRMFA technique where, using a sensor array, measurements may be made of the stray flux in open air and/or along a calibration bar (a calibration run) to help determine edge biasing of the sensors at the ends of the flux sensor array in an exciter/sensor array module, which is defined to include the windings and core of an exciter, a sensor array, and a sensor PCB together as a unit. This edge biasing measurement may be used to compensate for non-uniformities in the exciter field at the edges of the exciter, allowing for more complete use of the non-contact exciter's axial length for the array of flux sensors.

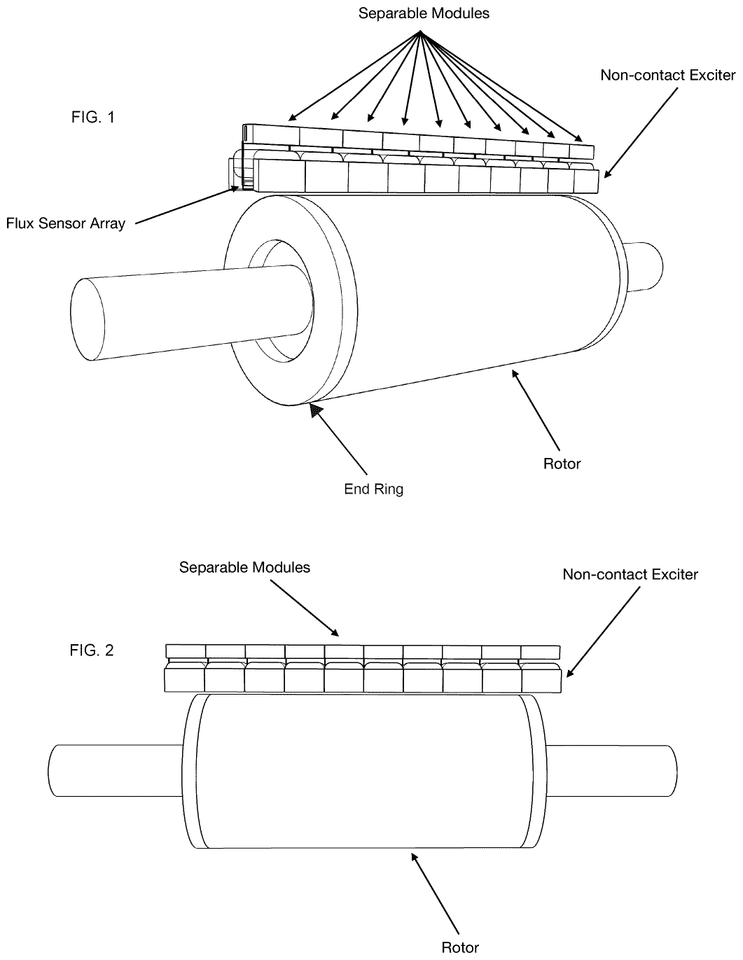

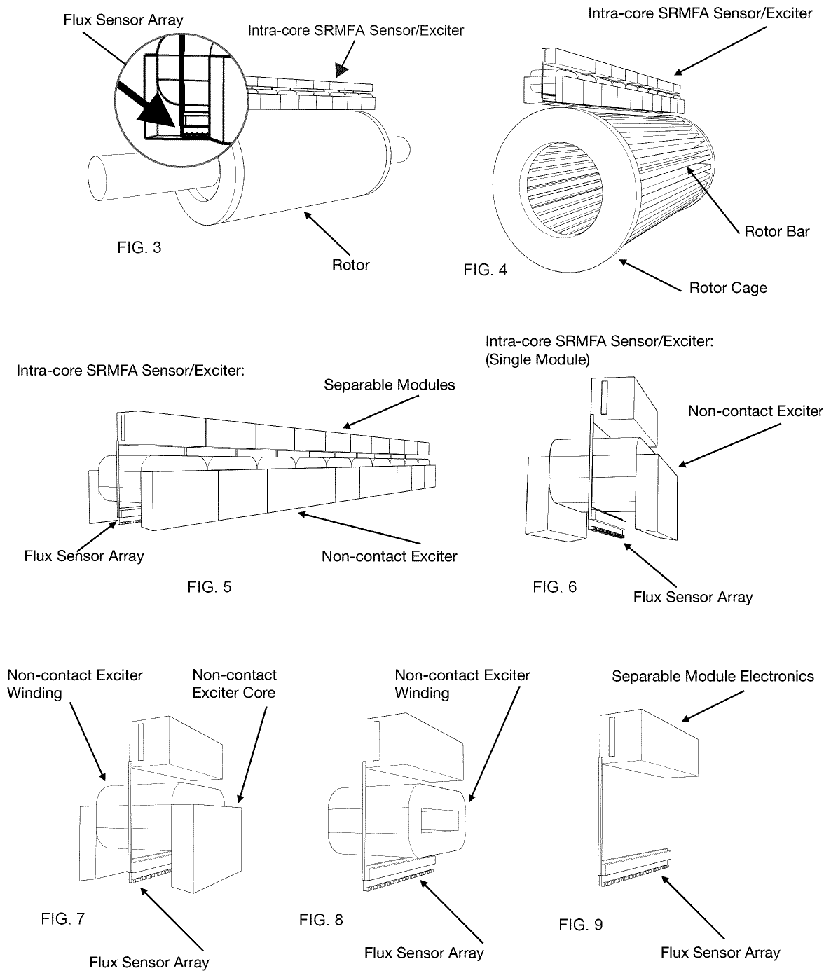

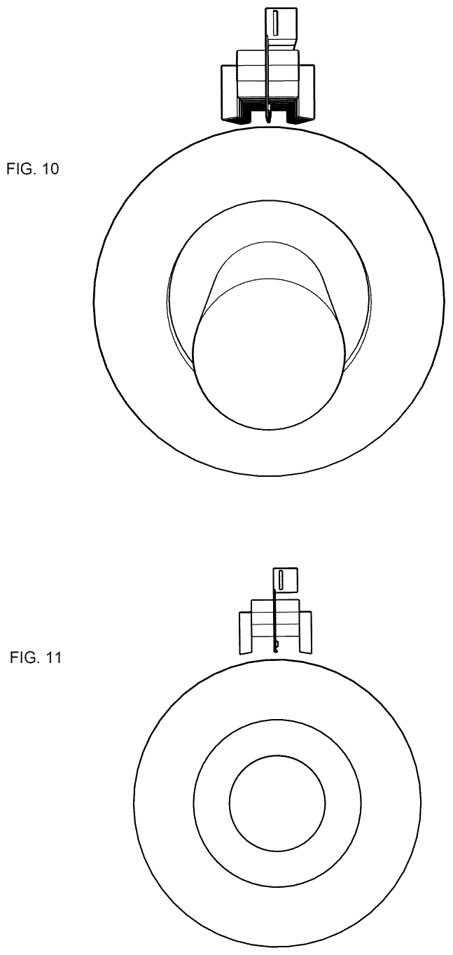

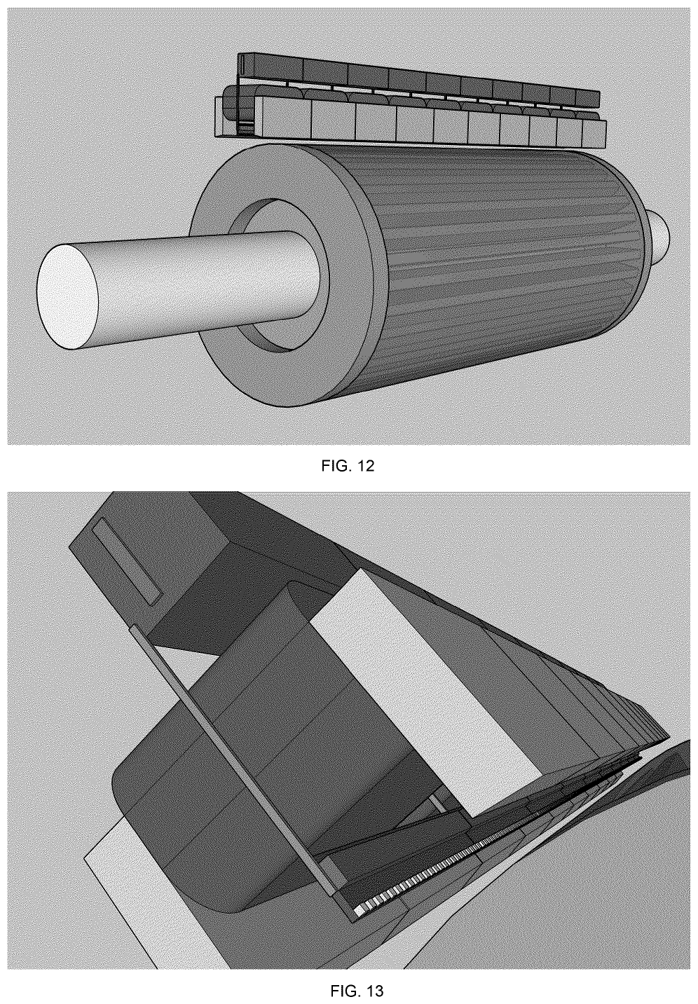

Besides the new data processing technique, the new system and method uses an array of the exciter/sensor modules placed end-to-end to accommodate variable rotor lengths. Preferably, the number of exciter/sensor array modules placed end-to-end in the array is sufficient to extend axially from one end of the rotor to be tested to the other end of the rotor, including the end rings, as shown in FIGS. 1 and 2. The array of exciter/sensor modules thus allows a full surface rotor cage flux map to be developed over the full axial extent of the rotor in a single rotor rotation. It should be understood that it is also possible instead to use one such module (or more than one of such modules also placed end-to-end as an array, but whose total axial extent is shorter than that shown in FIGS. 1 and 2) to make similar maps. In these cases, successive flux readings may be obtained by moving or stepping the one module (or the shorter array of modules) through adjacent axial positions along the axial length of the rotor.

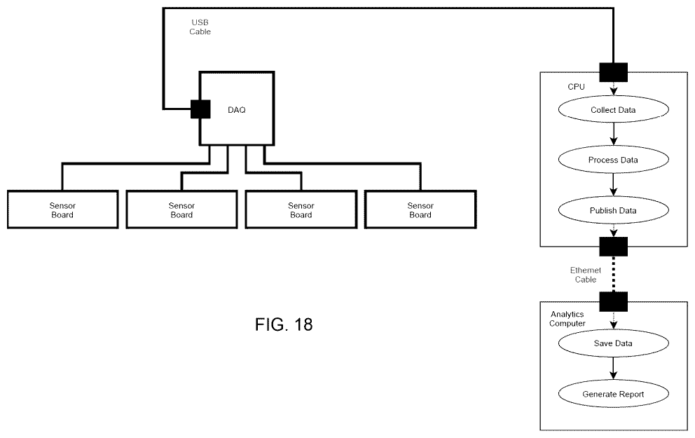

More specifically with regard to the data processing technique described above, sensor data may be collected from a calibration run in air or using a calibration bar with an exciter in a module (or using exciters in an array of modules) in the IcsRMFA topology. These data are used in an extra processing step in a CPU or processing computer (see CPU block in FIG. 18) to determine a compensation factor used to adjust values taken from sensor measurements or readings of sensors located near the edges of the individual module or module array due to a non-uniform magnetic flux at the opposite ends of the module or module array. This post processing step requires an arbitrary sensor to be selected (typically the middle sensor in a sensor array of a module or the middle sensor if more than one module is used in a module array) from which to adjust the other sensor data. To implement this compensation, a minimum from the selected sensor's time domain signal taken during a test run with a rotor under test is chosen whose value is closest to the mean value determined from all of the minima collected from sensor signal readings of all of the other sensors in a module or module array. The selected minimum may be chosen, for example, not to exceed one standard deviation from this mean value, although in other cases, it may be more than one standard deviation or may use some other criteria, for example, using a root mean (RMS) technique). This chosen minimum value is then used to calculate compensation factors used as multipliers of data (as the processing step also in the CPU shown in FIG. 18) related to the sensor readings taken from each sensor in the module or module array to determine a final compensated dataset.

The compensation described above is applied after collecting data during IcsRMFA testing of a rotor where the sensors are over the rotor, and an exciter(s) is(are) used as an excitation source(s). With the IcsRMFA testing system and method described herein to identify bad or defective rotor bars or end rings in rotors under test, we have been able to overcome (or lesson the effects of) prior direct current injection efficiency issues and flux band blinding, as described above, together allowing for flux level sensitivity sufficient to minimize the effects of closed slot residual flux biasing.

FIG. 18 combines a block diagram and flowchart showing components and data flow of the new IcsRMFA system and method described herein. Each sensor board includes a linear sensor array and its associated electronics co-located or integrated with a corresponding exciter as described herein. Each exciter/sensor array module or module array may be used to excite and sense flux data over a corresponding axial extent of the rotor bars and/or end rings under test as a function of the angular position of the rotor under test. These data are received from the sensor board(s) in the module(s) by a data acquisition (DAQ) unit, which performs sampling through its analog-to-digital conversion sampling hardware that communicates via USB to a processing computer (see CPU block in processing computer in FIG. 18). The processing computer collects the data from the DAQ and stores it in RAM or other volatile memory media, where it is analyzed and then published or transferred via ethernet to an analytics computer where it is saved in a database in non-volatile media, such as a magnetic hard drive or SSD. Part of the processing performed in the processing computer includes performing a fast Fourier transform (FFT) of the data sensor received from the DAQ. The primary frequency of interest is 60 Hz based on the power frequency supplied to the exciter/sensor array module(s), although use of other frequencies could be used, such as 50 Hz, are contemplated. Note that although the flowchart of FIG. 18 shows a distributed computing implementation in a network environment, all of the functions and processes related thereto, as described herein, could instead be performed by a single computer or even in more computers. Further, the computers may be servers and distributed memory may be used for data or database storage.

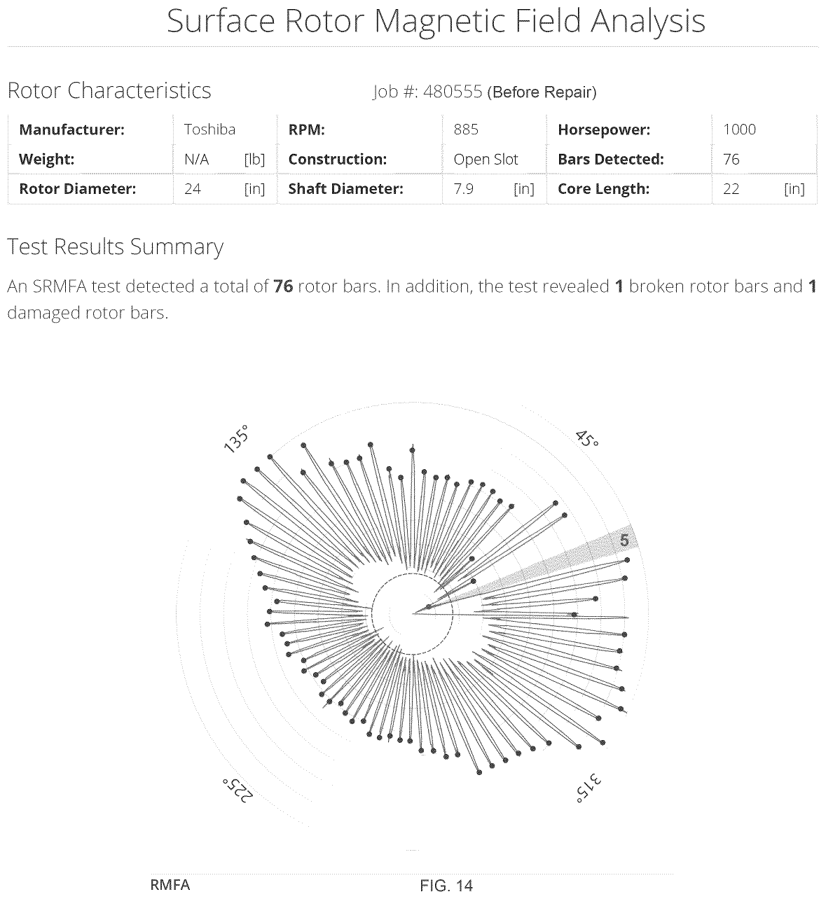

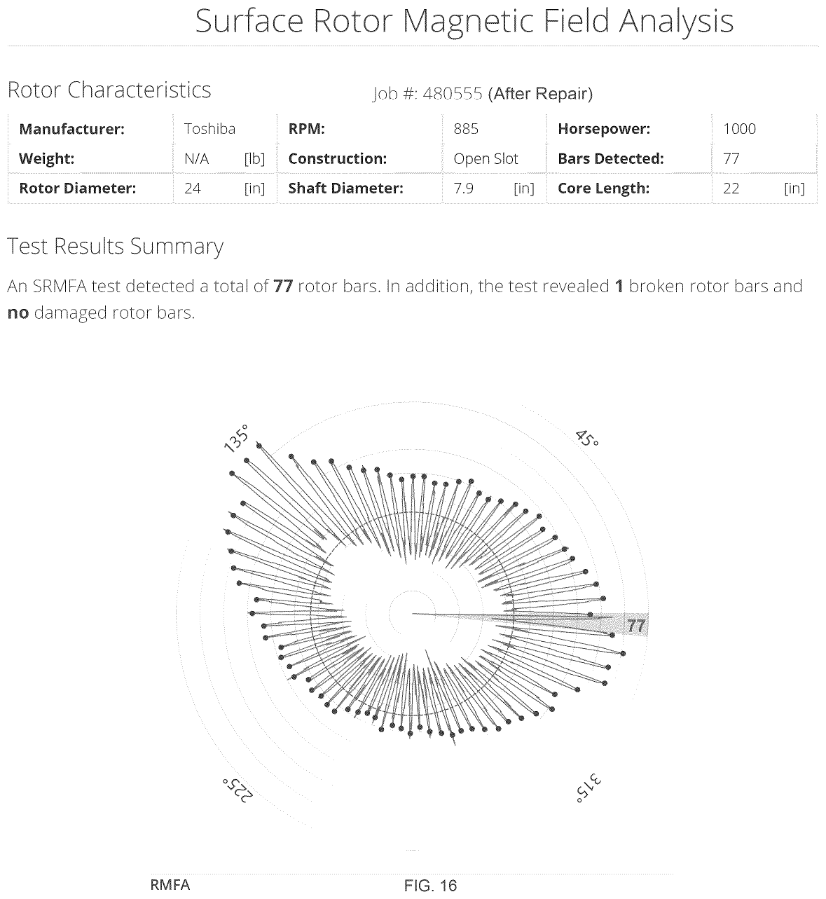

The saved data may be used by the analytics computer to generate a report or test report (see Sheets 5/11 through 7/11 and Sheets 8/11 through 10/11) that includes information and plots, such as polar plots (e.g., as shown in FIGS. 14 and 16), related to the analysis of the rotor bars. The polar plots show normalized flux data magnitudes as a function of rotor bar angular position produced by an exciter/sensor array module or module array that can be used to identify which rotor bars or end rings of a rotor are damaged or defective, if any. The set of concentric circles in the polar plots may indicate how the data is normalized, such as, for example, 25%, 50%, 75%, and 100% of a normalized unitless magnitude related to the flux of the particular rotor bar exhibiting the highest flux tested. Each radial endpoint in the polar plots indicates the normalized unitless magnitude obtained from each corresponding rotor bar (identified by number) measured by one sensor in a module or in a module array over a full rotation (through 360 degrees) of the rotor under test. It may be that rotor bars falling within and including the 50% or 75% magnitude circles indicate rotors having rotor bars acceptable for use or passing a test by a rotor manufacturer, user, or customer whose rotor is being manufactured or tested.

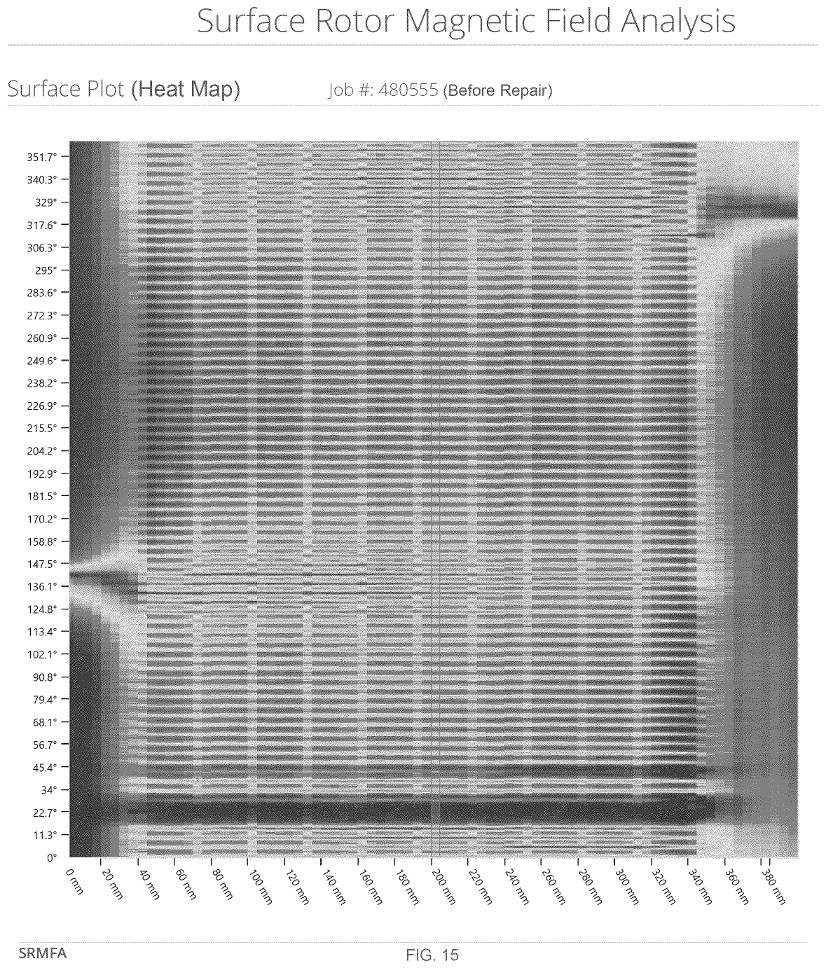

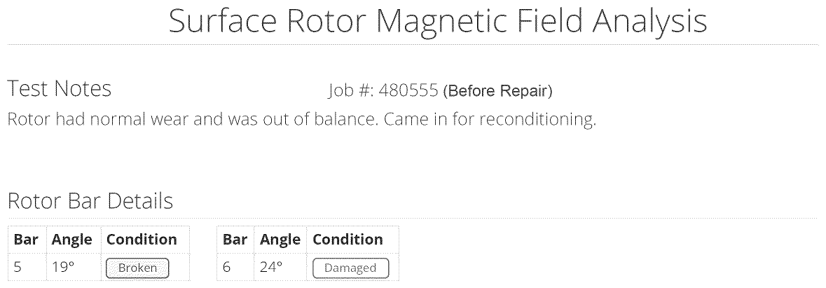

Sheets 5/11 through 7/11, which include FIGS. 14 and 15, were obtained by testing a particular rotor needing repair. As shown in the polar plot of FIG. 14, rotor bar 5 centered at about 22.7 degrees (or of rotor rotation) appears to be broken as shown by its peak magnitude and rotor bar 6 whose magnitude is next to it on the plot counterclockwise appears to be damaged as shown by its peak magnitude (note that a rotor bar will occupy a certain angular extent depending on the width of the rotor bar and the number of rotor bar used in a rotor may depend on the size of the rotor). This damage can be seen in the corresponding decreased magnitudes for bar 5 and 6 in FIG. 14. In this case, the threshold for determining whether a rotor bar is damaged or defective is chosen to be at 25% of the magnitude of the particular rotor bar having the maximum flux measured of all of the rotor bars. Note that zero (0) degrees is defined to be at the angular midpoint between rotor bar 1 (arbitrarily chosen from the set of rotor bars) and the last rotor bar in the rotor. FIG. 15 is a heat map in color, which may also be used to identify damaged or defective rotor bars. Heat maps show, for each rotor bar and its adjacent portion of the end rings, the measured values related to the flux for each rotor in color as a function of angular rotation (Y-axis) of the rotor relative to 0 degrees and also as a function of distance along the axial length of the rotors (X-axis). The blue color generally indicates low flux (although normalized and unitless at this point), which may indicate a broken or damaged bar. At the other end of the spectrum, red indicates a high or higher flux (again although normalized and unitless at this point), which may indicate unbroken or undamaged bars. The heat map of FIG. 15 shows blue color at about 22.7 degrees in the vicinity of rotor bars 5 and 6, which again indicates rotor bar 5 may be broken and rotor bar 6 may be damaged. The two parallel vertical lines in the center of FIG. 15 demarcate a portion of the heat map for a particular sensor. This data from this sensor was used to create the polar plot of FIG. 14. The data of other sensors could have been used instead to create a similar polar plot to FIG. 14.

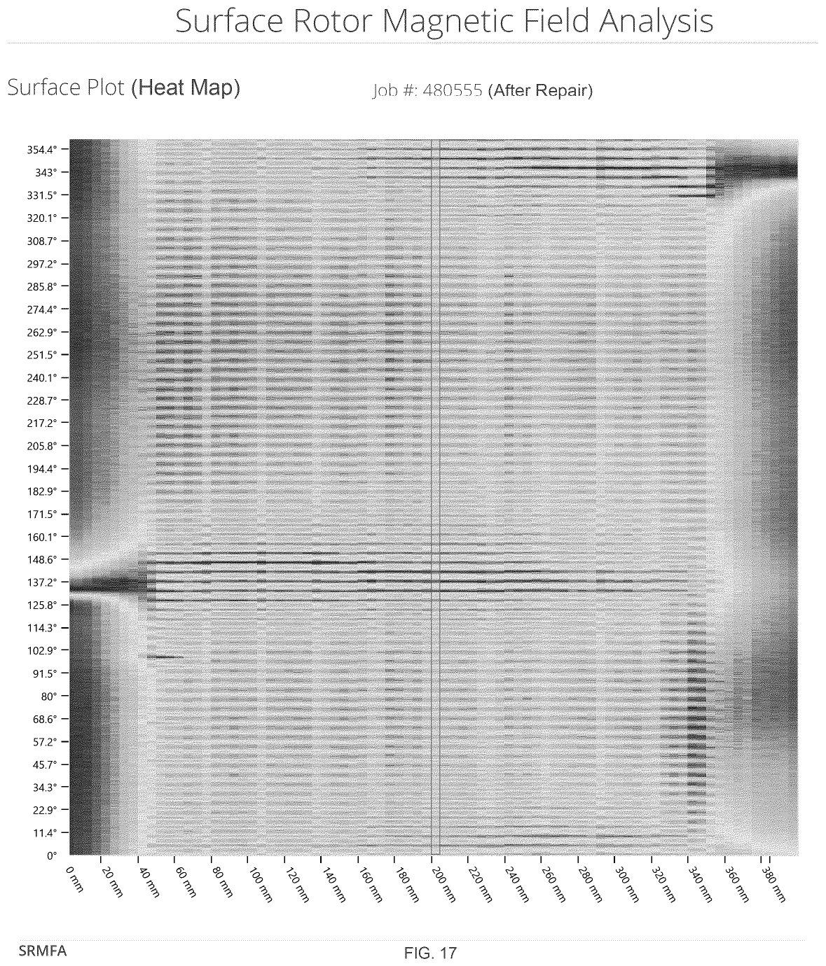

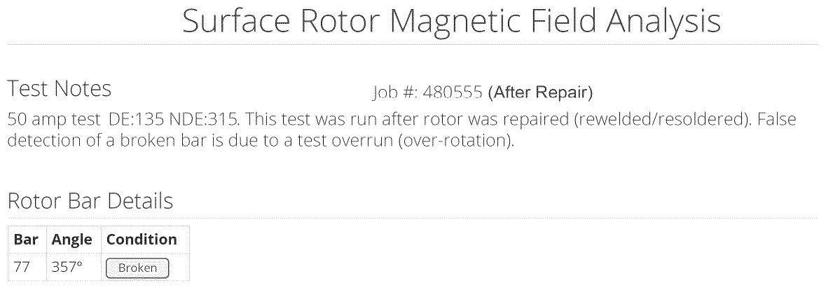

Sheets 8/11 through 10/11, which include FIGS. 16 and 17, show tests performed on the same rotor of FIGS. 14 and 15 after it was repaired, for example, by rewelding/resoldering or replacing rotor bars 5 and 6. The polar plot of FIG. 16 and the heat map of FIG. 17 are similar to those of FIGS. 14 and 15, and appear to indicate that the repaired rotor is now good. Note, although the polar plot of FIG. 16 and sheet 10/11 appear to indicate that rotor bar 77 was broken after repair, this was not the case. It was an artifact due to a test overrun (over-rotation) of the rotor during testing.

The disclosed system and method may provide several advantages over prior techniques, such as, at least:
1. Eliminating the need for axial displacement of excitation source and sensor from RMFA.
2. Minimizing the impact of residual flux biasing found in closed slot rotor testing.
3. Eliminating the need for direct end ring injection methods in sRMFA testing.
4. Simplifying operation of the testing unit with respect to current injection.
5. Improving applicability in that both open slot and closed designs may be tested, opening the entire range of motor power designs for testing.
6. Simplifying manufacturing because the exciter and sensor array effectively become one unit or module.
7. Allowing for one module to be used as a handheld unit for small rotors, further simplifying the testing process.
8. Allowing for commercialized closed slot/open slot rotor defect testing apparatus.

It should be emphasized and understood that the embodiments described herein are merely examples of possible implementations. Many variations and modifications may be made to the embodiments, as would be understood by one of ordinary skill in the art, without departing from the principles of the present disclosure. All such modifications and variations are intended to be included herein within the scope of this disclosure.

1. A system and method for induction motor intra-core rotor bar surface magnetic field analysis, comprising:
a flux sensor array; and
a non-contact excitor having core limbs, wherein said flux sensor array is disposed between said core limbs of said non-contact excitor.
